(19) United States
(12) Patent Application Publication
(10) Pub. No.: US 2011/0175664 A1
(43) Pub. Date: Jul. 21, 2011

(54) ELECTRONIC CIRCUIT

(75) Inventors: Junpei INOUE, Kanagawa (JP); Naoki YADA, Kanagawa (JP); Sadayuki MORITA, Kanagawa (JP); Kazuki FUKUOKA, Kanagawa (JP)

(73) Assignee: RENESAS ELECTRONICS CORPORATION

(21) Appl. No.: 12/987,556

(22) Filed: Jan. 10, 2011

(30) Foreign Application Priority Data
Jan. 15, 2010 (JP) 2010-006418

(51) Int. Cl. H03L 5/00

(52) U.S. Cl. 327/333; 327/306

(57) ABSTRACT

A power-supply sequence-free electronic circuit is realized without the increase of the number of power supply detectors for detecting the rising of the power supply. The electronic circuit operated by supplying three or more types of power supply voltages to the ground voltage of the circuit generates a first detection signal indicating whether any one of other power supply voltages does not rise by a first detection circuit which is operated with a predetermined power supply voltage as an operation power supply. The electronic circuit generates a second detection signal indicating whether the predetermined power supply voltage rises by a second detection circuit which is provided for each of the other power supply voltages and operated with one power supply voltage of the other power supply voltages as an operation power supply. The electronic circuit generates a control signal for ensuring the rising of other power supply voltages for each of the other power supply voltages based on the first and second detection signals.

### CROSS-REFERENCE TO RELATED APPLICATIONS

The disclosure of Japanese Patent Application No. 2010-6418 filled on Jan. 15, 2010 including the specification, drawings and abstract is incorporated herein by reference in its entirety.

### BACKGROUND OF THE INVENTION

The present invention relates to an electronic circuit and, in particular, to a technique effectively applicable to a microcomputer operated by a plurality of power supplies.

In an electronic circuit requiring a plurality of types of power supplies, for example, in a microcomputer with multiple power supplies, when a signal is transferred between circuits operated by a different power supply voltage, a through current resulting from input unstable propagation can be generated depending on the order of rising or falling of the power supply. For example, in a predetermined circuit operated by receiving an output signal from another circuit using a predetermined power supply as an operation voltage and using another power supply as an operation voltage, let us suppose that the predetermined power supply rises, but the another power supply does not rise. In this case, the voltage level of output signal from the another circuit is unstable to make the input of the predetermined circuit unstable, thereby the through current can flow through the predetermined circuit.

Thus, the through current is generated, a wasteful current consumption is increased in the microcomputer. The generation of rush current based on the sudden through current damages elements and wirings in the microcomputer to lower reliability. Particularly, in a case where an external regulator for supplying a power supply the microcomputer exists, current exceeding load current permitted by the regulator can flow, which may affect the regulator. For this reason, an electronic circuit requiring a plurality of power supplies needs to detect the rising and the falling of the power supply, perform a control based on the rising and the falling, and avoid through current resulting from the input unstable propagation.

Conventionally, Japanese Unexamined Patent Publication No. 2005-286082 discloses a technique for preventing the through current.

The method described in Japanese Unexamined Patent Publication No. 2005-286082 is such that a power supply switch for performing control for supplying a power supply to an internal circuit is provided in a semiconductor integrated circuit and the power supply switch is controlled by a power supply switch controller to cut off a path through which the through current flowing in a case where the input signal of the internal circuit is unstable and leak current flowing on standby.

### SUMMARY OF THE INVENTION

When the input unstable propagation and the through current are prevented by the method described in Japanese Unexamined Patent Publication No. 2005-286082 or other methods, the rising of the power supply voltage previously needs detecting to perform the above control based on the detection result. The detection of the power supply voltage is realized by a power supply detector for detecting the rising of the another power supply voltage with one power supply voltage as an operation voltage.

In most conventional electronic circuits such as microcomputer with multiple power supplies, the order of turning on a power supply, or a power supply sequence is prescribed. In such a case, the rising of all other power supply voltages can be detected by the power supply detector using a power supply which first rises as an operation power supply, for example, so that the input unstable propagation and the through current can be prevented by performing the control with use of the method described in Japanese Unexamined Patent Publication No. 2005-286082 or other methods using the detection result.

However, it is not easy to control a power supply sequence because the power supply sequence needs controlling by the entire system including a power supply IC such as the external regulator and other external apparatus. In recent years, there has been a strong demand for making free a power-supply sequence so that an electronic circuit is stably operated without being affected irrespective of turning on a power supply in whatever sequence. However, it is not easy for a power-supply sequence-free microcomputer having multiple power supplies to detect the rising of the power supply voltage as described above. For the case of being the power-supply sequence-free, for example, since a first starting power supply is unclear, the rising of all power supply voltages cannot be ensured unless one power supply voltage is taken as an operation power supply and the power supply detector for detecting that all other power supply voltages rise is prepared by the number of power supplies. If the number of power supplies is N, for example, N×(N−1) power supply detectors are required. Thus, a large number of the power supply detectors according to the number of power supplies is required to realize making free the power-supply sequence of an electronic circuit. For the case of a microcomputer with multiple power supplies formed over a single semiconductor substrate, for example, a chip area needs to be increased, which causes a problem in that cost is increased.

The object of the present invention is to provide a power-supply sequence-free electronic circuit without increasing the number of the power supply detectors for detecting the rising of the power supply.

The foregoing and other objects and novel features of the present invention will become apparent from the following description and accompanying drawings of the present application.

The outline of representative inventions out of the those disclosed in the present application is briefly described below.

An electronic circuit operated by supplying three or more types of power supply voltages to the ground voltage of the circuit generates a first detection signal indicating whether any one of other power supply voltages does not rise by a first detection circuit which is operated with a predetermined power supply voltage as an operation power supply. The electronic circuit generates a second detection signal indicating whether the predetermined power supply voltage rises by a second detection circuit which is provided for each of the other power supply voltages and operated with one power supply voltage of the other power supply voltages as an operation power supply. The electronic circuit generates a control signal for ensuring the rising of other power supply voltages for each of the other power supply voltages based on the first and second detection signals.

Advantages obtained by representative inventions out of the those disclosed in the present application are briefly described below.

A power-supply sequence made free can be realized without substantially increasing the number of the power supply detectors for detecting the rising of the power supply.

### BRIEF DESCRIPTION OF THE DRAWINGS

FIG. 1 shows a power-supply sequence-free microcomputer with multiple power supplies according to a first embodiment;

FIG. 2 is a block diagram of a power supply detection circuit 10 in a microcomputer 1;

FIG. 3 shows an example of circuit configuration of a power supply detector 101_A to 101_F;

FIG. 4 is an example of circuit configuration of a level shift circuit 103_A;

FIGS. 5A and 5B are examples of a sequence of power supplies input into the microcomputer 1;

FIG. 6 is another example of circuit configuration of the level shift circuit 103_A;

FIG. 7 is an example of the microcomputer 1 formed over a single semiconductor substrate;

FIG. 8 is an example of a graph showing an area of the power supply detector formed over the semiconductor substrate; and

FIG. 9 is an example of a microcomputer 1B including an internal circuit 20_H incorporating a power supply switch.

### DETAILED DESCRIPTION OF THE PREFERRED EMBODIMENTS

### 1. Outline of Embodiments

The outline of representative embodiments of the invention disclosed in the present application is briefly described below. The parenthesized reference numerals and characters in the drawings in the description of outline of representative embodiments are merely exemplify something included in concepts of composing elements to which the reference numerals and characters are attached.

[1] An electronic circuit (1) according to a representative embodiment of the present invention is the one which is operated by supplying three or more types of power supply voltages to the ground voltage of the circuit. The electronic circuit (1) includes a power supply detection circuit (10) for detecting the rising of all the power supply voltages to generate a plurality of control signals for ensuring the rising of other power supply voltages for each power supply voltage and a plurality of internal circuits (20_A to 20_H) with the power supply voltage as an operation power supply for each power supply voltage. The internal circuits include gate circuits (202A, 202B, and 905) for making effective the input of a signal supplied from another circuit with another power supply voltage as an operation power supply when the rising of the power supply voltage excluding its own power supply voltages is ensured by the control signal. The power supply detection circuit includes a first detection circuit (101) which is operated with a predetermined power supply voltage as an operation power supply and generates a first detection signal (104_1) indicating whether any one of other power supply voltages does not rise, a second detection circuit (102 and 102_A to 102_F) provided for each of the other power supply voltages which is operated with one power supply voltage of the other power supply voltages as an operation power supply and generates a second detection signal (106_A to 106_F) indicating whether the predetermined power supply voltage rises, and a signal generation circuit (103 and 103_A to 103_F) provided for each of the other power supply voltages which generates the control signals (104_2 to 104_7) for ensuring the rising of other power supply voltages for each of the other power supply voltages based on the first and second detection signals. Thereby, the following effects and advantages are obtained.

The first detection signal can ensure that any of the other power supply voltages does not rise and the second detection signal can ensure that the predetermined power supply voltage does not rise. However, the first detection signal cannot identify whether any of power supply voltages does not rise. If the power supply voltage being the operation voltage of the second detection circuit does not rise, the second detection signal is unreliable. Furthermore, if the power supply voltage being the operation voltage of the signal generation circuit does not rise, the control signal is unreliable. Whether the power supply voltage being the operation voltage of the second detection circuit and the signal generation circuit rises is neglected and the control signal ensuring that any of all the power supply voltages excluding the power supply voltage does not rise is input to the internal circuit with the power supply voltage as the operation voltage. Thereby, an unstable propagation to the internal circuit can be prevented until the risk is eliminated that any of all the power supply voltages excluding the operation voltage of the internal circuit does not rise.

The number of the power supply detectors required for the electronic circuit is 2×(N−1).

[2] In the electronic circuit in the above item [1], the signal generation circuit includes a first level shift circuit (401) which is operated with one power supply voltage of the other power supply voltages as an operation voltage, converts the voltage level of the first detection signal to that of one power supply voltage of the other power supply voltages and outputs the first detection signal and an output gate circuit (402) for outputting the control signal based on the second detection signal. If the rising of the predetermined power supply voltage is ensured by the second detection signal, the output gate circuit outputs the output signal of the first level shift circuit as the control signal. If the rising of the predetermined power supply voltage is not ensured by the second detection signal, the output gate circuit outputs a signal for fixing the output of the gate circuit to a constant voltage as the control signal. Thereby, a signal ensuring the rising of other power supply voltages excluding operation voltage of the first level shift circuit can be generated.

[3] In the electronic circuit in the above items [1] or [2], the first detection circuit includes a third detection circuit (101_A to 101_F) which is operated with the predetermined power supply voltage as an operation power supply and generates a third detection signal indicating whether one power supply voltage of the other power supply voltages rises for each of the other power supply voltages and a detection signal generation unit (105) for outputting a logical product for all the third detection signals as the first detection signal. Thereby, a first detection signal can be easily generated.

[4] In the electronic circuit in the above item [3], the detection signal generation unit is formed by coupling a plurality of AND gate circuits in series.

[5] In any of the electronic circuits in the above items [1] to [4], the internal circuit further includes a second level shift circuit (203A and 203B) at the front stage of the gate circuit. The second level shift circuit converts the voltage level of a signal input from a circuit excluding the internal circuit to the voltage level of the internal circuit. This can easily prevent the unstable propagation of an output signal in the second level shift circuit.

[6] In any of the electronic circuits in the above items [1] to [5], the internal circuit (20_H) further includes a switch element (901) performing control for supplying a power supply to the internal circuit. The switch element is controlled by the output of the gate circuit (905). This can easily prevent the unstable propagation of a signal for controlling the switch element.

[7] In the electronic circuits in the above items [1] or [2], a first region (701) where the internal circuit is formed, a second region (70 to 73) where a circuit for an external interface is formed, and a third region (704_A to 704_D) which is not used for the first and second regions are provided for a single semiconductor substrate. The power supply detection circuit is formed in one or both of the second and third regions. Thus, the power supply detection circuit is formed of a small number of the power supply detectors, so that the power supply detection circuit can be formed in an unused region existing in the semiconductor substrate, which does not substantially increase the area of the semiconductor substrate.

[8] In the electronic circuit in the above item [7], the first detection circuit includes the third detection circuit (101_A to 101_F) which is operated with the predetermined power supply voltage as an operation power supply and generates the third detection signal indicating whether one of the other power supply voltages rises for each of the other power supply voltages and the detection signal generation unit which is formed by coupling a plurality of AND gate circuits (105_B to 105_F) in series and outputs a logical product for all the third detection signals as the first detection signal. Thereby, the effect similar to that in the item (3) is achieved.

[9] In the electronic circuit in the above item [8], the AND gate circuit is discretely formed in one or both of the second and third regions. This can suppress the redundant route of wiring related to the third detection signal.

[10] In the electronic circuit in the above item [9], the second region further includes a plurality of electrostatic discharge prevention element forming regions (703_A to 703_C) used for the formation of the power supply detection circuit.

[11] In the electronic circuit in the above item [10], the electrostatic discharge prevention element forming region includes the second detection circuit and the signal generation circuit with any of the other power supply voltages as an operation power supply, the third detection circuit for generating the third detection signal related to the other power supply voltages, and the AND gate circuits. Thus, the composing element of the power supply detection circuit is formed for each electrostatic discharge prevention element forming region, so that design can be readily changed even if the number of the other power supply voltages is changed according to the specifications of the electronic circuit.

### 2. Detailed Description of Embodiments

The embodiments are described in detail below.

### First Embodiment

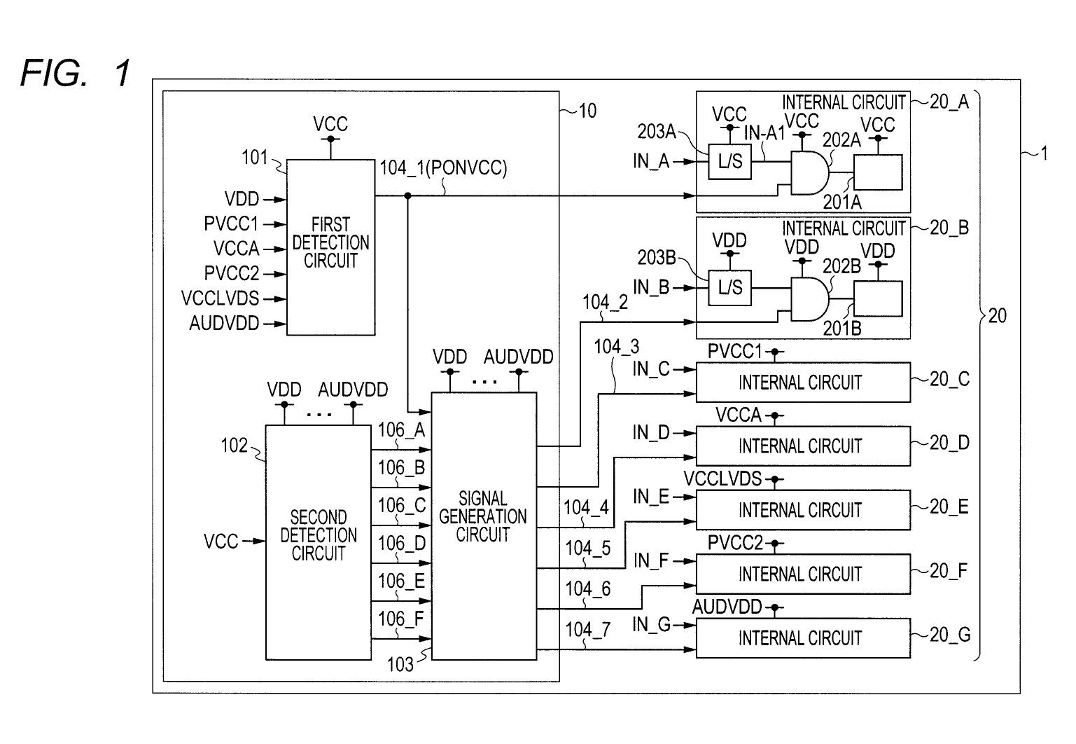

FIG. 1 shows a power-supply sequence-free microcomputer with multiple power supplies according to an embodiment of the present invention.

A microcomputer 1 shown in FIG. 1 is a microcomputer for a power train of an automobile, for example.

A plurality of types of power supply voltages is input to the microcomputer 1 shown in FIG. 1. In this example, seven types of power supplies of VCC, VDD, PVCC 1, VCCA, VCCLVDS, PVCC 2, and AUDVDD. The VCC is a power supply for a system, the VDD is a power supply for a logic circuit, the VCCA is a power supply for an analog circuit. The PVCCs 1 and 2 are power supplies for a port system. The VCCLVDS is a power supply for a low voltage differential signaling (LVDS) system. The AUDVDD is a power supply for debugging the microcomputer 1.

The microcomputer 1 includes a power supply detection unit 10 for detecting the rising of all the input power supply voltages and a plurality of internal circuits 20_A to 20_G for realizing the functions of the microcomputer 1.

The power supply detection unit 10 includes a first detection circuit 101, a second detection circuit 102, and a signal generation circuit 103.

The first detection circuit 101 uses a power supply voltage VCC as an operation power supply, detects whether other six types of the power supplies rise, and outputs a control signal 104_1 (PONVCC). A method for generating the control signal is described in detail later.

The second detection circuit 102 uses the other six types of the power supply voltages as an operation power supply, detects whether power supply voltage VCC rises, and outputs detection signals 106_A to 106_F with voltage levels of the other six types of the power supply voltages respectively.

The signal generation circuit 103 generates six control signals 104_2 to 104_7 (PONVDD, PONPVCC1, PONVCCA, PONVCCLVDS, PONPVCC2, AND PONAUDVDD) based on the detection signals 106_A to 106_F of the second detection circuit 102. The six control signals are the ones for indicating whether the other six types of the power supply voltages excluding the predetermined power supply voltage rise. For example, the control signal 104_2 (PONVDD) is the one indicating whether other six power supply voltages excluding the VDD rises. A method for generating the control signal is described in detail later.

The internal circuits 20_A to 20_G are those which are operated with any one of the seven types of power supply voltages as an operation voltage. As a typical example, the internal circuit 20_A is described below.

The internal circuit 20_A includes a gate circuit 202A, an internal block circuit 201A, and a level shift circuit 203A and each circuit is operated with the VCC as an operation power supply.

The internal block circuit 201A is the one for performing a predetermined operation based on a signal IN_A generated by other circuits with any of other six types of power supply voltages excluding the VCC as an operation voltage.

The level shift circuit 203A provides the gate circuit 202A with a signal IN_A1 in which the voltage level of the signal IN_A is converted to the voltage level of the power supply voltage VCC.

The gate circuit 202A is the one controlling whether to provide the signal IN_A1 for the internal block circuit 201A at the rear stage thereof based on the control signal PONVCC. The gate circuit 202A is an AND circuit for outputting a logical product of input. Even if the gate circuit 202A is taken as a NAND circuit, the object can be achieved.

The other internal circuits 20_B to 20_G are similar to the internal circuit 20_A in circuit configuration and operated by different power supply voltages respectively and the control signals 104_2 to 104_7 corresponding to respective power supply voltages are inputted thereto.

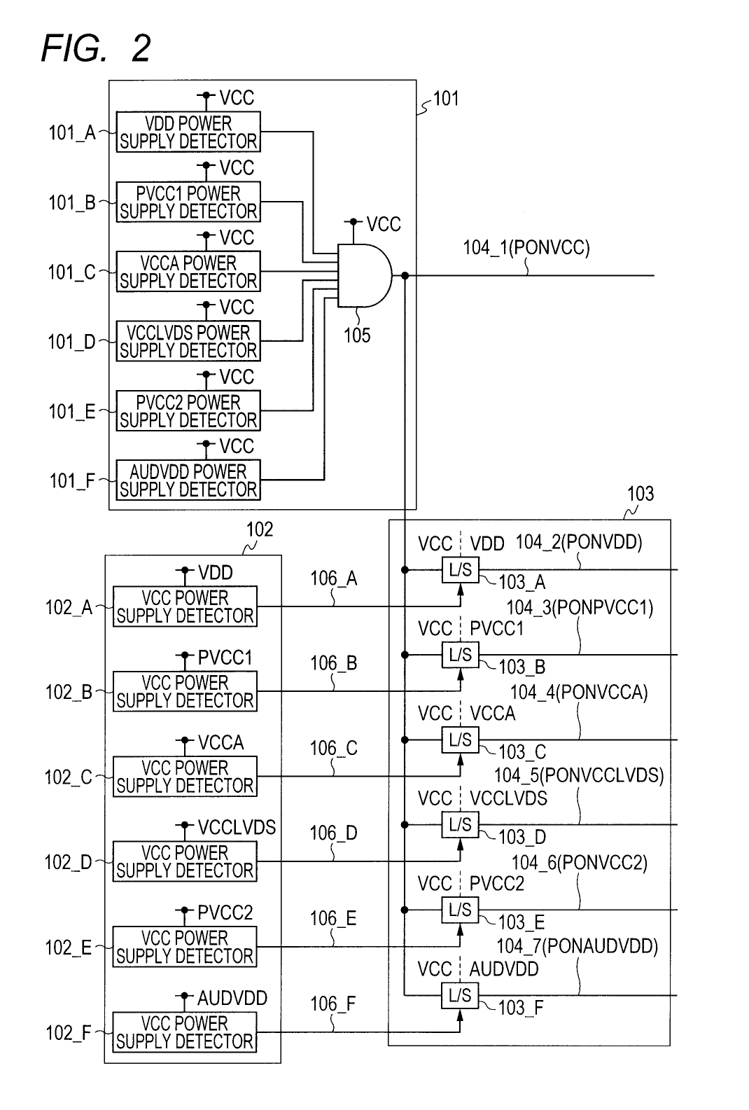

A method for generating the control signals 104_1 to 104_7 is described in detail below with reference to FIG. 2.

FIG. 2 shows an example of circuit configuration of the first detection circuit 101, the second detection circuit 102, and the signal generation circuit 103 in the power supply detection circuit 10.

A method for generating the control signal 104_1 (PONVCC) with the first detection circuit 101 is described below.

The first detection circuit 101 includes power supply detectors 101_A to 101_F and an AND gate circuit 105 which are operated with the power supply voltage VCC as an operation voltage.

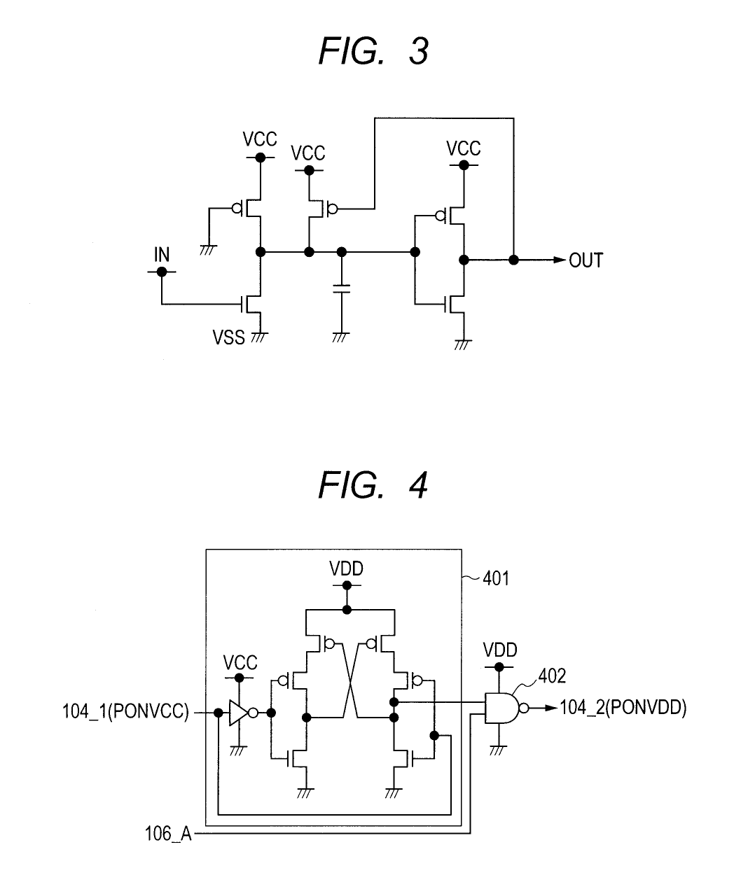

FIG. 3 shows an example of circuit configuration of the power supply detectors 101_A to 101_F.

The power supply detectors 101_A to 101_F receive any of other six types of power supply voltages excluding the VCC as an input signal IN and output an output signal OUT as a high level when the input signal IN exceeds a predetermined value. For the power supply detector 101_A, for example, when the power supply voltage VDD rises, the power supply detector 101_A outputs the output signal OUT as a high level. When the power supply voltage VDD does not rise, the power supply detector 101_A outputs the output signal OUT as a low level. The high level of the output signal OUT is equal to the voltage level of the power supply voltage VCC. The low level of the output signal OUT is equal to a ground level (VSS).

The output signal OUT of each of the power supply detectors 101_A to 101_F is input into the AND gate circuit 105. The AND gate circuit 105 outputs the logical product of the input as the control signal 104_1 (PONVCC). The logical product gate circuit 105 is an AND circuit, for example. If any one of other six types of power supply voltages excluding the VCC does not rise, the control signal PONVCC is rendered to be a low level.

The AND gate circuit 105 may be a NAND circuit. Furthermore, the AND gate circuit 105 may be formed of one AND circuit with multiple inputs as shown in FIG. 2 or a plurality of AND circuits coupled to each other in series.

The thus generated control signal PONVCC is a signal indicating whether other six types of power supply voltages excluding the VCC rise. If the VCC being the operation voltage of the power supply detectors 101_A to 101_F and the AND gate circuit 105 does not rise, the control signal PONVCC becomes unstable, so that the control signal PONVCC is unreliable. Then, the control signal PONVCC is used as the control signal of the internal circuit 20_A operated by inputting a signal from a circuit with any of other six types of power supply voltages excluding the VCC as the operation voltage to allow a control for capturing an input into the internal circuit 20_A.

For example, if other six types of power supply voltages excluding the VCC do not rise in the internal circuit 20_A into which the PONVCC is input as a control signal, the gate circuit 202A outputs a signal fixed to a low level to the internal block circuit 201A irrespective of the signal IN_A1 to be input. Thereby, through current resulting from input unstable propagation of the internal block circuit 201A can be prevented from being generated until the risk is eliminated that other six types of the power supply voltages excluding the VCC do not rise.

If the VCC does not rise, the control signal PONVCC becomes unstable as stated above, however, the internal circuit 20_A with the VCC as the operation power supply does not operate either, so that there is no risk that through current resulting from input unstable propagation flows.

A method for generating the control signals 104_2 to 104_7 by the signal generation circuit 103 is described below. As a typical example, a method for generating the control signal 104_2 (PONVDD) is described.

In FIG. 2, the second detection circuit 102 includes power supply detectors 102_A to 102_F.

The power supply detectors 102_A to 102_F are similar to the power supply detectors 101_A to 101_F in circuit configuration.

The power supply detectors 102_A to 102_F use other six types of power supply voltages excluding the VCC as operation voltages respectively. For example, the power supply detector 102_A uses the VDD as an operation voltage and the power supply detector 102_F uses the AUDVDD as an operation voltage.

The power supply detectors 102_A to 102_F receive the VCC as the input signal IN and detects whether the VCC rises. For example, the power supply detector 102_A outputs the detection signal 106_A being an output signal as a high level when the VCC rises. The power supply detector 102_A outputs the detection signal 106_A as a low level when the VCC does not rise. For the power supply detector 102_A, the high level is equal to the voltage level of the power supply voltage VDD and the low level is equal to the voltage level of ground (VSS).

The signal generation circuit 103 is formed of the level shift circuits 103_A to 103_F with the detection signals 106_A to 106_F as control signals.

FIG. 4 is an example of circuit configuration of the level shift circuit 103_A with the VDD as the operation voltage. The other level shift circuits 103_B to 103_F are similar to the level shift circuit 103_A in circuit configuration, but different in the operation voltage and control signal.

The level shift circuit 103_A shown in FIG. 4 includes a level shift unit 401 and an output gate circuit 402.

The level shift unit 401 converts the control signal PONVCC being the voltage level signal of the power supply voltage VCC into a voltage level.

The output gate circuit 402 outputs the control signal PONVDD based on the detection signal 106_A. At this point, whether the level shift unit 401 outputs the level shift signal as the control signal PONVDD is controlled by the detection signal 106_A output from the power supply detector 102_A.

For example, if the VCC does not rise, i.e., if the detection signal 106_A is in a low level, the level shift circuit 103_A outputs the control signal 104_2 (PONVDD) fixed to a low level irrespective of the signal level of the control signal PONVCC to be input. If the VCC rises, i.e., if the detection signal 106_A is in a high level, the level shift circuit 103_A outputs a signal in which the voltage level of the control signal PONVCC is shifted to the VDD by the level shift unit 401 as the control signal PONVDD.

The following becomes apparent with respect to the thus generated control signal PONVDD.

As described above, the control signal PONVCC can ensure that any of all the power supply voltages excluding the VCC does not rise. The detection signal 106_A can ensure that the VCC does not rise. However, the control signal PONVCC cannot identify whether any of all the power supply voltages excluding the VCC does not rise. The detection signal 106_A and the control signal PONVDD become unreliable in a case where the VDD being the operation voltage of the power supply detector 102_A and the level shift circuit 103_A does not rise. More specifically, the control signal PONVDD neglects whether the VDD rises and ensures that any of all the power supply voltages excluding the VCC does not rise. Inputting the control signal PONVDD into the internal circuit 20_B with the VDD as the operation voltage allows preventing the generation of through current resulting from input unstable propagation of the internal block circuit 201B. For example, in the internal circuit 20_B, if other six power supply voltages excluding the VDD do not rise, the control signal PONVDD is rendered to be a low level and the gate circuit 202B outputs a signal fixed to a low level to the internal block circuit 201B. Thereby, through current resulting from input unstable propagation of the internal block circuit 201B can be prevented from being generated until the risk is eliminated that all the power supply voltages excluding the VCC do not rise. If the VCC does not rise, the control signal PONVDD becomes unstable as stated above, however, the internal circuit 203B with the VCC as the operation power supply does not operate either, so that there is no risk that through current resulting from input unstable propagation flows.

The other control signals 104_3 to 104_7 excluding the control signal 104_2 are generated in the method similar to the above and achieve the similar effect.

According to the first embodiment, a power-supply sequence-free microcomputer 1 can be easily realized.

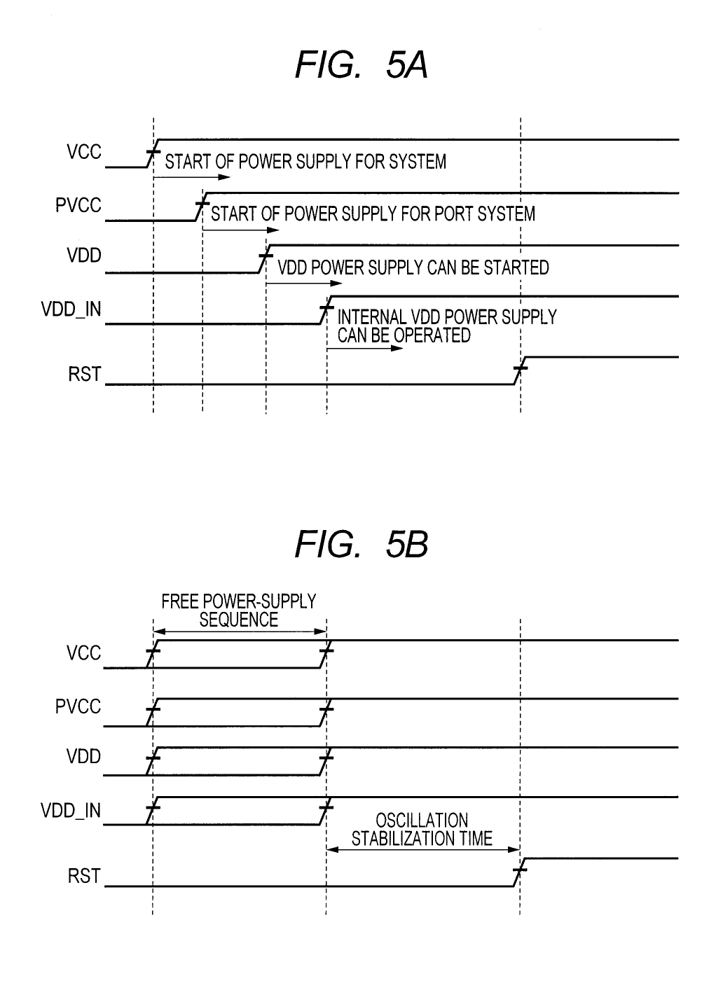

FIGS. 5A and 5B show examples of a power-supply sequence input into the microcomputer 1.

FIG. 5A describes a conventional example of a sequence of rising of a power supply.

FIG. 5B describes an example of being power-supply rising sequence-free.

In FIGS. 5A and 5B, VCC, PVCC1 and VDD denote power supply voltages input into the microcomputer 1. For the sake of description, three power supply voltages are definitely represented. VDD_IN is an internal power supply actually supplied to the internal circuit of the microcomputer 1 and RST is a reset signal of the microcomputer 1.

As shown in FIG. 5A, in the past, in order to avoid the problem of the input unstable propagation, a power supply rising sequence has needed to be defined such that the VCC being the power supply voltage of a system is started, the PVCC1 being the power supply voltage of a port system is started, and then the VDD being the power supply voltage of a logic circuit is started. According to the first embodiment, as shown in FIG. 5B, the input unstable propagation can be prevented without the power supply rising sequence being defined and the microcomputer 1 can be safely operated.

If attention is drawn to the number of the power supply detectors required for making free the free power-supply sequence, according to the first embodiment, making free the power-supply sequence can be realized by 12 power supply detectors including six power supply detectors 101_A to 101_F in the first detection circuit 101 and six power supply detectors 102_A to 102_F in the second detection circuit 102. More specifically, if the number of the power supplies input into an electronic circuit such as a microcomputer is N (N is an integer of 2 or more), making free the power-supply sequence for the electronic circuit can be realized by 2(N−1) power supply detectors. This allows a substantial decrease in the number of the power supply detectors as compared with a conventional method requiring N(N−1) power supply detectors for making free the power-supply sequence for the electronic circuit.

The power supply detection unit 10 according to the first embodiment is applicable to an electronic circuit into which two or more power supplies are input. Applying the power supply detection unit 10 to an electronic circuit into which three or more power supplies allows obtaining the effect for suppressing increase in the number of the power supply detectors.

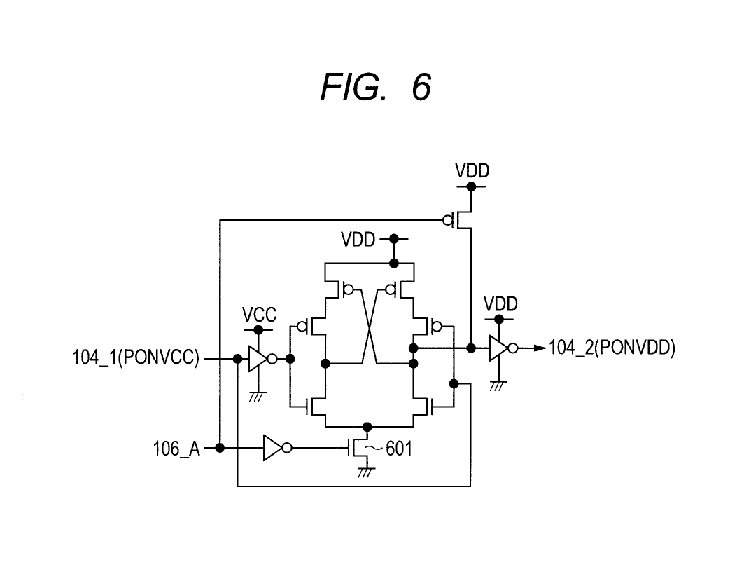

As an example of circuit configuration of the level shift circuits 103_A to 103_F, a circuit configuration shown in FIG. 6 may be used instead of the circuit configuration shown in FIG. 4.

FIG. 6 is another example of circuit configuration of the level shift circuit 103_A.

The circuit configuration shown in FIG. 6 achieves an effect similar to that shown in FIG. 4 and enables the transistor 601 to prevent the through current of the level shift circuit based on the unstable propagation of the input signal PONVCC.

### Second Embodiment

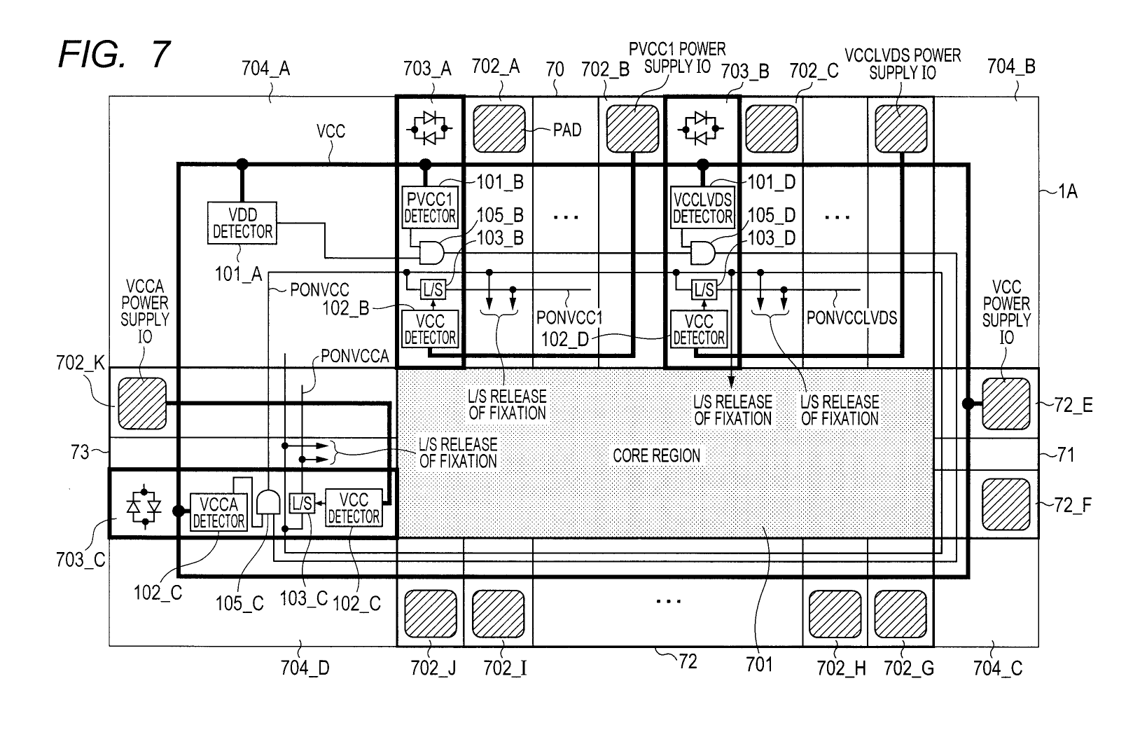

FIG. 7 shows an example of the microcomputer 1 formed over a single semiconductor substrate.

FIG. 7 shows only circuits and wirings related to main power supplies for the sake of description.

The microcomputer 1 in FIG. 7 is roughly divided into three regions.

The three regions include a core regions 701 where the internal circuit 20 is formed, I/O regions 70 to 73 where an external interface circuit such as a PAD being an input output terminal and a protection element is formed, and other regions.

The I/O regions 70 to 73 prevent a power-supply short circuit between power supplies and include bridge cell regions 703_A to 703_C where a bidirectional diode coupled between power supplies to protect electrostatic discharge (ESD) is formed and PAD formation regions 702_A to 702_K where the PAD is formed.

Other regions are those formed of corner cell regions 704_A to 704_D arranged at the corners of the chip.

There are more unused regions in the I/O regions 70 to 73 and the corner cell regions 704_A to 704_D than in the core region 701. The unused regions are scattered about the I/O regions 70 to 73 and the corner cell regions 704_A to 704_D.

In the microcomputer 1, the power supply detection unit 10 is dispersed, formed, and wired in the scattered unused regions. More specifically, the circuit blocks being the composing elements of the first detection circuit 101, the second detection circuit 102, and the signal generation circuit 103 are intensively formed in predetermined regions for each corresponding power supply.

For example, the power supply detector 101_B for detecting the PVCC1, and the power supply detector 102_B and the level shift circuit 103_B which use the PVCC1 as the operation power supply are formed in the bridge cell region 703_A.

The bridge cell region 703_A is arranged, for example, in the vicinity of an I/O region 702_B where the PAD of the corresponding power supply PVCC1 is formed. This allows lowering the wiring resistance of the power supply line for supplying power to the power supply detector 102_B and the level shift circuit 103_B.

Similarly, other circuit blocks are also formed in the bridge cell regions 703_A to 703_C for each corresponding power supply.

The AND gate circuit 105 in the first detection circuit 101 is formed of not a multiple-input AND circuit but a plurality of two-input AND circuits 105_A to 105_C coupled with each other in series and scatteredly arranged as described above. More specifically, the AND circuits 105_A to 105_C are scatteredly arranged in the corner cell regions 704_A to 704_D or the I/O regions 70 to 73. For example, the AND circuit 105_A is formed in the bridge cell region 703_A related to the PVCC1. The AND circuit 105_D is formed in the bridge cell region 703_B related to the VCCLVDS. Forming the AND gate circuit 105 for sequentially generating a logical product of the output signal of each two-input AND circuit and the detection signals of the power supply detectors 101_A to 101_F in the bridge cell regions allows finally generating the control signal PONVCC. For example, the detection signals of the power supply detectors 101_A and 101_B are input into the AND circuit 105_B. The output signal of the AND circuit 105_B and the detection signal of the power supply detector 101_D are input into the AND circuit 105_D. The wiring related to the control signal PONVCC generated by the AND circuits thus coupled in series is routed to the bridge cell regions 703_A to 703_C and input into the level shift circuits 103_B to 103_D.

Thus, scatteredly forming the AND gate circuits 105 allows forming the wiring for the detection signals of the power supply detectors 101_A to 101_F input to the AND gate circuits 105 without the wiring being more redundantly routed than that in a multiple-input AND circuit.

The power supply detectors related to the circling power supply may be arranged in the corner cell regions 704_A to 704_D. For example, if the wiring of a power supply VDD (not shown) is wired so as to circle the core region 701, similarly to that of the power supply VCC, the power supply detector 101_A may be arranged in the corner cell region 704_A as shown in FIG. 7.

As described above, the composing elements of the power supply detection unit 10 are scatteredly formed using the unused regions scattered about the I/O regions 70 to 73 and the corner cell regions 704_A to 704_D to enable suppressing substantial increase in chip area of the microcomputer 1 caused by making free the power-supply sequence.

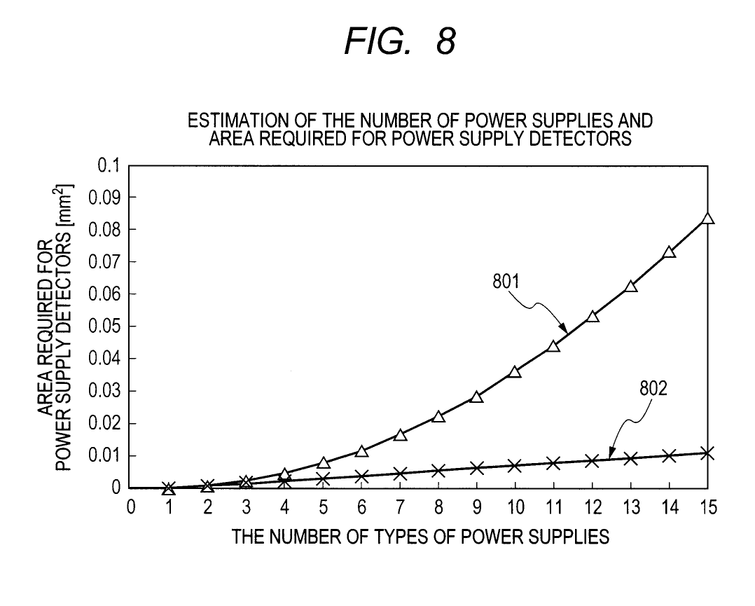

FIG. 8 is an example of a graph showing an area required for forming the power supply detector needed for making free the power-supply sequence of the microcomputer 1 over a semiconductor substrate.

In FIG. 8, the abscissa indicates the number of power supplies input into the electronic circuit and the ordinate indicates the total area of the power supply detectors. An area per one power supply detector is taken as 400 μm² as an example.

In FIG. 8, a curve indicated by a reference numeral 801 shows the total area of the power supply detectors in the conventional method which requires N(N−1) power supply detectors for making free the power-supply sequence. A straight line indicated by a reference numeral 802 shows the total area of the power supply detectors in a case where the power supply detection unit 10 is applied to the power-supply sequence made free.

As shown in FIG. 8, according to the second embodiment, the greater the number of power supplies, the more realizable the power-supply sequence-free scheme which more substantially suppresses increase in area than that in the conventional method. For example, if the number of power supplies is 10, an area can be reduced by approximately 80% as compared with the one reduced by the conventional method.

As described above, since the bridge cell regions 703_B to 703_D are arranged and required power supply wirings are coupled to the bridge cell regions 703_B to 703_D to form the circuit blocks of the power supply detection unit 10, design can be readily changed even if the number of power supplies is changed according to the specifications of the microcomputer 1. For example, if the power supply VCCA is not used and short circuited to the VSS, the power supply detector 101_C for detecting the rising of the VCCA continues detecting that the power supply does not rise, so that the bridge cell region 703_C cannot be kept arranged as it is. In such a case, the bridge cell region 703_C is replaced with a standard bridge cell region where the block circuit of the power supply detection unit 10 is nor formed to allow easily adapting to design change.

### Third Embodiment

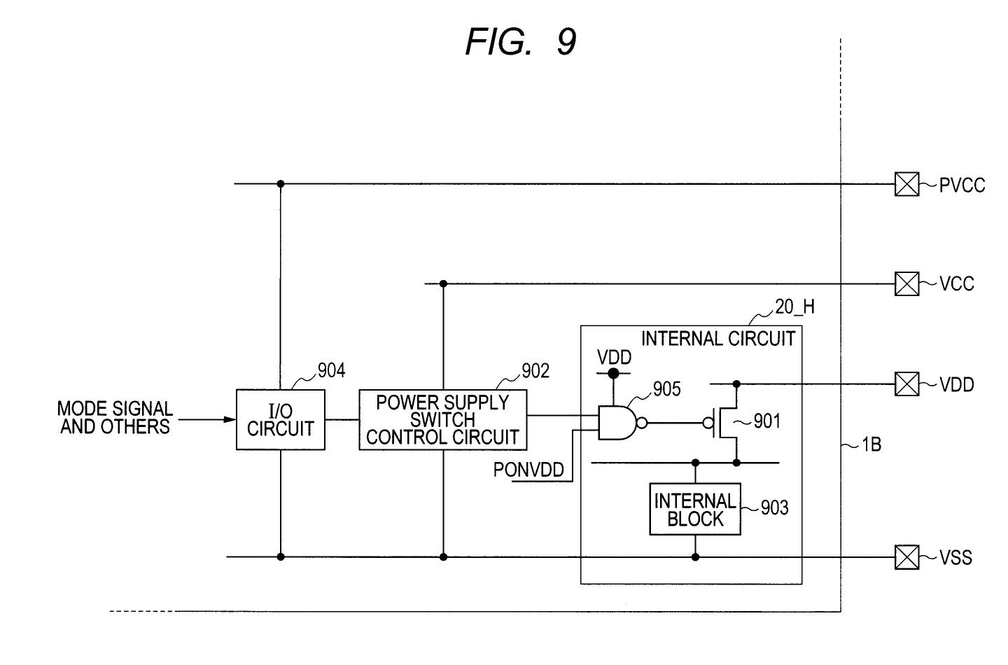

FIG. 9 shows a microcomputer 1B including an internal circuit 20_H incorporating a power supply switch for avoiding leak current on standby.

The microcomputer 1B shown in FIG. 9 further includes the internal circuit 20_H, a power supply switch control circuit 902, and an I/O circuit 904 in addition to the composing elements of the microcomputer 1. FIG. 9 shows only main circuits for the sake of description.

The internal circuit 20_H includes an internal block circuit 903, a power supply switch 901, and a gate circuit 905.

The internal block circuit 903 is a circuit for performing a predetermined operation with the power supply voltage VDD as the operation voltage. The internal block circuit 903 is a logic circuit and a random access memory (RAM), for example.

The power supply switch 901 is arranged between the internal block circuit 903 and the power supply line of the power supply voltage VDD and acts as a switch controlling the supply of the power supply voltage VDD to the internal block circuit 903. The power supply switch 901 is controlled by the power supply switch control circuit 902. The power supply switch 901 is a metal oxide semiconductor (MOS) transistor, for example. Here, the power supply switch 901 uses a P-type MOS transistor.

As is the case with the abovementioned gate circuit 203A, the gate circuit 905 controls whether to provide the control signal from the power supply switch control circuit 902 for the power supply switch 901 at the rear stage based on the control signal PONVDD. The gate circuit 905 is a NAND circuit for outputting the logical product of the inputs, for example.

The I/O circuit 904 generates the control signal of the power supply switch control circuit 902 based on the signal input from the outside of the microcomputer 1B or from another internal circuit of the microcomputer 1B. The signal input into the I/O circuit 904 is a mode signal for determining the operation mode of the internal block circuit 903, for example.

The power supply switch control circuit 902 controls turning on and off the power supply switch 901 based on the control signal from the I/O circuit 904. For example, when the power supply switch control circuit 902 receives the control signal requesting the internal block circuit 903 to stop operation from the I/O circuit 904, the power supply switch control circuit 902 turns off the power supply switch 901 to stop the supply of power supply to the internal block circuit 903. This allows reducing sub-threshold leak current during the standby of the internal block circuit 903.

As described above, the power supply switch 901 receives a signal via the gate circuit 905 without directly receiving the control signal from the power supply switch control circuit 902 as the control signal, so that the power supply switch 901 is allowed to be brought into an OFF state until the risk is eliminated that all the other power supply voltages excluding the VDD do not rise, which enables the power supply switch 901 to be controlled by the control signal PONVDD. In addition, through current resulting from unstable propagation of the input signal from the power supply switch control circuit 902 can be prevented.

The microcomputer 1B may be formed into a single semiconductor circuit similarly to the microcomputer 1A. For example, the internal circuit 20_H and the power supply switch control circuit 902 are formed in the core region 701 and the I/O circuit 904 is formed in any of the I/O regions 70 to 73. The power supply detection unit 10 is formed similarly to that in the microcomputer 1A to achieve the effect similar to that in the microcomputer 1A.

The invention made by the present inventors is described in detail based on the embodiments heretofore. It is to be understood that the present invention is not limited to the embodiments, but various changes may be made without departing from the gist and scope of the invention.

In the microcomputer 1, for example, further detecting the rising of the operation voltage VCCPLL of a phase locked loop (PLL) circuit for generating an internal clock signal allows a control for stopping the operation of the microcomputer 1 until the operation voltage VCCPLL rises, i.e., until the clock signal is generated. For example, a power supply detector 101_G for detecting the rising of the VCCPLL with the VCC as the operation power supply is further provided in the first detection circuit and the detection signal of the power supply detector 101_G is input into the AND gate circuits 105. A power supply detector 102_G for detecting the rising of the VCC with the VCCPLL as the operation power supply is provided in the second detection circuit and a level shift circuit 103_G with the VCCPLL as the operation voltage is provided in the signal generation circuit 103. This achieves the similar effect described above and allows a control for stopping the operation of the microcomputer 1 until the clock signal is generated.

In the third embodiment, the gate circuit 905 is provided at the front stage of the power supply switch 901, but a gate circuit similar to the gate circuit 905 in configuration may be provided at the front stage of the power supply switch control circuit 902. This allows preventing the input unstable propagation to the power supply switch control circuit 902 until the risk is eliminated that all the other power supply voltages excluding the VCC do not rise.

What is claimed is:

1. An electronic circuit operated by supplying three or more types of power supply voltages to the ground voltage of the circuit, comprising:
a power supply detection circuit configured to detect the rising of all the power supply voltages to generate a plurality of control signals for ensuring the rising of other power supply voltages for each power supply voltage; and
a plurality of internal circuits with the power supply voltage as an operation power supply for each power supply voltage,
wherein each of the internal circuits includes a gate circuit for making effective the input of a signal supplied from another circuit with another power supply voltage as an operation power supply when the rising of the power supply voltage excluding its own power supply voltages is ensured by the control signal and the power supply detection circuit includes a first detection circuit which is operated with a predetermined power supply voltage as an operation power supply and generates a first detection signal indicating whether any one of other power supply voltages does not rise, a second detection circuit which is provided for each of the other power supply voltages and operated with one power supply voltage of the other power supply voltages as an operation power supply and generates a second detection signal indicating whether the predetermined power supply voltage rises, and a signal generation circuit provided for each of the other power supply voltages which generates the control signal for ensuring the rising of other power supply voltages for each of the other power supply voltages based on the first and second detection signals.

2. The electronic circuit according to claim 1, wherein the signal generation circuit includes: a first level shift circuit which is operated with one power supply voltage of the other power supply voltages as an operation voltage, converts the voltage level of the first detection signal to that of one power supply voltage of the other power supply voltages and outputs the first detection signal; and an output gate circuit for outputting the control signal based on the second detection signal, wherein, the output gate circuit outputs the output signal of the first level shift circuit as the control signal if the rising of the predetermined power supply voltage is ensured by the second detection signal and outputs a signal for fixing the output of the gate circuit to a constant voltage as the control signal if the rising of the predetermined power supply voltage is not ensured by the second detection signal.

3. The electronic circuit according to claim 2, wherein the first detection circuit includes a third detection circuit operated with the predetermined power supply voltage as an operation power supply and generates a third detection signal indicating whether one power supply voltage of the other power supply voltages rises for each of the other power supply voltages and a detection signal generation unit for outputting a logical product for all the third detection signals as the first detection signal.

4. The electronic circuit according to claim 3, wherein the detection signal generation unit is formed by coupling a plurality of AND gate circuits in series.

5. The electronic circuit according to claim 1, wherein the internal circuit further includes a second level shift circuit at the front stage of the gate circuit and the second level shift circuit converts the voltage level of a signal input from a circuit excluding the internal circuit to the voltage level of the internal circuit.

6. The electronic circuit according to claim 1, wherein the internal circuit further includes a switch element performing control for supplying a power supply to the internal circuit and the switch element is controlled by the output of the gate circuit.

7. The electronic circuit according to claim 1, wherein a first region where the internal circuit is formed, a second region where a circuit for an external interface is formed, and a third region which is not used for the first and second regions are provided for a single semiconductor substrate, and the power supply detection circuit is formed in one or both of the second and third regions.

8. The electronic circuit according to claim 7, wherein the first detection circuit includes the third detection circuit operated with the predetermined power supply voltage as an operation power supply and generates the third detection signal indicating whether one of the other power supply voltages rises for each of the other power supply voltages and the detection signal generation unit which is formed by coupling a plurality of AND gate circuits in series and outputs a logical product for all the third detection signals as the first detection signal.

9. The electronic circuit according to claim 8, wherein the AND gate circuit is discretely formed in one or both of the second and third regions.

10. The electronic circuit according to claim 9, wherein the second region further includes a plurality of electrostatic discharge prevention element forming regions which are used for the formation of the power supply detection circuit.

11. The electronic circuit according to claim 10, wherein the electrostatic discharge prevention element forming region includes the second detection circuit and the signal generation circuit with any of the other power supply voltages as an operation power supply, the third detection circuit for generating the third detection signal related to the other power supply voltages, and the AND gate circuits.
